(19) United States
(12) Patent Application Publication
(10) Pub. No.: US 2007/0263756 A1
(43) Pub. Date: Nov. 15, 2007

(54) MOBILE COMMUNICATION TERMINAL HAVING CLOCK CONTROL FUNCTION AND CLOCK CONTROL METHOD FOR THE SAME

(75) Inventor: Sang Chul Shin, Bucheon-si (KR)

Correspondence Address: LEE, HONG, DEGERMAN, KANG & SCHMADEKA, 660 S. FIGUEROA STREET, Suite 2300, LOS ANGELES, CA, 90017, US

(73) Assignee: LG Electronics Inc.

(21) Appl. No.: 11/619,169

(22) Filed: Jan. 2, 2007

(30) Foreign Application Priority Data
Jan. 2, 2006 (KR) 10-2006-0000147

(51) Int. Cl. H03D 3/02

(52) U.S. Cl. 375/373

(57) ABSTRACT

A mobile communication terminal having a clock control function and a clock control method for the same are provided. The terminal includes a first oscillator configured to produce a first clock having a frequency which is not affected by interference from a specific channel, a second oscillator configured to produce a second clock having a frequency different from the frequency of the first clock, and a mixer configured to mix the first clock and the second clock and output a third clock as the mixing result. This prevents channel interference when receiving signals through a specific channel.

This application claims the priority benefit of Korean Patent Application No. 10-2006-0000147, filed on Jan. 2, 2006, which is hereby incorporated by reference as if fully set forth herein.

### BACKGROUND OF THE INVENTION

1. Field of the Invention

The present invention relates to a mobile communication terminal, and more particularly, to a mobile communication terminal having a clock control function, which prevents channel interference, and a clock control method for the same.

2. Discussion of the Related Art

A Global System for Mobile communications (GSM) is a digital wireless communication technology that is a modification of the Time Division Multiple Access (TDMA). The GSM is widely used together with the TDMA and the Code Division Multiple Access (CDMA). The GSM is the wireless communication standard in Europe. Worldwide, the GSM has 120 million users in about 120 countries.

The GSM has evolved to Enhanced GSM (EGSM) which extends the existing band to accommodate a rapidly increasing number of users. The EGSM uses a backward band of 880-915 MHz and a forward band of 925-960 MHz.

A conventional GSM system for a mobile communication terminal will now be described with reference to FIG. 1.

As shown in FIG. 1, two clocks (i.e., high and slow clocks) are used to keep the conventional GSM system in operation. The high clock of the GSM system is maintained at 13 MHz and the slow clock is maintained at 32.768 KHz. The GSM system uses the high clock with frequency of 13 MHz as a main clock.

However, the harmonic frequency (or component) of the frequency of the high clock (i.e., 13 MHz) equals the reception frequencies of 5th and 70th channels in the EGSM frequency band. In other words, 13 MHz multiplied 72 times (13 MHz×72) equals 926 MHz which is the reception frequency (Rx) of the 5th channel and, 13 MHz multiplied 73 times (13 MHz×73) equals 949 MHz which is the reception frequency (Rx) of the 70th channel.

In the conventional technologies, the main clock of the mobile communication terminal causes severe interference to signals received through specific channels (particularly, the 5th and 70th channels) in the EGSM frequency hand since some harmonic components of the main clock are equal to the reception frequencies of the specific channels.

In addition, the reception sensitivity of audio signals received when performing voice communication through the specific channel is significantly reduced since the frequency of the main clock causes interference to the audio signals received through the specific channel.

Further, in a conventional mobile communication terminal which receives broadcast signals, the reception sensitivity of broadcast signals through a specific broadcast channel is significantly reduced since some harmonic components of a main clock of the mobile communication terminal for receiving the broadcast signals are equal to the reception frequency of the specific broadcast channel.

### SUMMARY OF THE INVENTION

Accordingly, the present invention is directed to a mobile communication terminal having a clock control function and a clock control method for the same that substantially obviate one or more problems due to limitations and disadvantages of the related art.

An object of the present invention is to provide a mobile communication terminal, which prevents interference with a channel when receiving wireless or broadcast signals through the channel, and a clock control method for the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a mobile communication terminal having a clock control function comprises a first oscillator configured to produce a first clock having a frequency which is unaffected by interference from a specific channel; a second oscillator configured to produce a second clock having a frequency different from the frequency of the first clock; and a mixer configured to mix the first clock and the second clock and output a third clock as the mixing result.

Preferably, the mobile communication terminal further comprises a radio frequency (RF) communication module configured to communicate a wireless signal with a base station; and a controller configured to control an operation associated with the communication of the wireless signal, wherein the mixer includes a first mixer and a second mixer, each of the first mixer and the second mixer mixes the first and second clocks and outputs a third clock as the mixing result. Here, the first mixer is included in the RF communication module and the second mixer is included in the controller.

Preferably, the mobile communication terminal further comprises a broadcast receiving module configured to receive a broadcast signal through a broadcast channel; and a controller configured to control an operation associated with the reception of the broadcast signal, wherein the mixer includes a first mixer and a second mixer, each of the first mixer and the second mixer mixes the first and second clocks and outputs a third clock as the mixing result. Here, the first mixer is included in the broadcast receiving module and the second mixer is included in the controller.

In another aspect of the present invention, a clock control method for a mobile communication terminal comprises producing a first clock having a frequency which is unaffected by interference from a specific channel; producing a second clock having a frequency different from the frequency of the first clock; and mixing the first clock and the second clock, and outputting a third clock as the mixing result.

Preferably, the clock control method further comprises receiving a wireless signal using the third clock as a main clock. Here, mixing the first and second clocks and outputting the third clock preferably includes mixing the first clock and the second clock in a module that receives the wireless signal and outputting the third clock.

Preferably, the clock control method further comprises receiving a broadcast signal through a broadcast channel using the third clock as a main clock. Here, mixing the first clock and the second clock and outputting the third clock preferably includes mixing the first and second clocks in a module that receives the broadcast signal and outputting the third clock.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a conventional GSM system for a conventional mobile communication terminal;

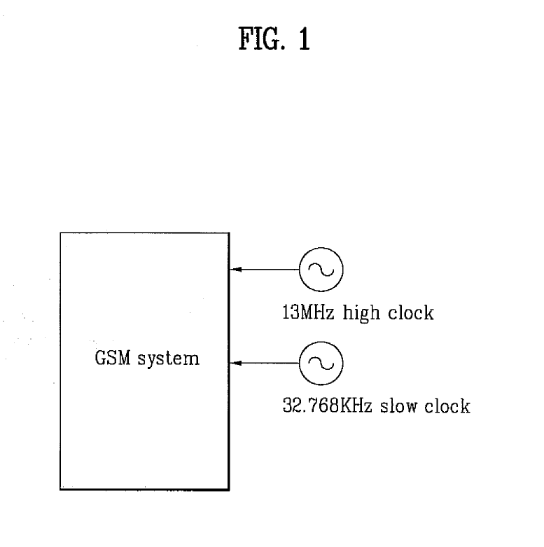

FIG. 2 is a block diagram of an embodiment of a mobile communication terminal that controls its clocks when receiving a wireless signal according to the present invention;

FIG. 3 is a block diagram of another embodiment of the mobile communication terminal that controls its clocks when receiving a wireless signal according to the present invention;

FIG. 4 is a block diagram of an embodiment of a mobile communication terminal that controls its clocks when receiving a broadcast signal according to the present invention;

FIG. 5 is a block diagram of another embodiment of the mobile communication terminal that controls its clocks when receiving a broadcast signal according to the present invention;

FIG. 6 is a schematic flow chart of a clock control method for a mobile communication terminal according to the present invention;

FIG. 7 is a detailed flow chart of an embodiment of a clock control method for a mobile communication terminal when receiving a wireless signal according to the present invention; and

FIG. 8 is a detailed flow chart of an embodiment of a clock control method for a mobile communication terminal when receiving a broadcast signal according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts. In the following description of the present invention, a detailed description of known functions and configurations incorporated herein will be omitted when it may obscure the subject matter of the present invention.

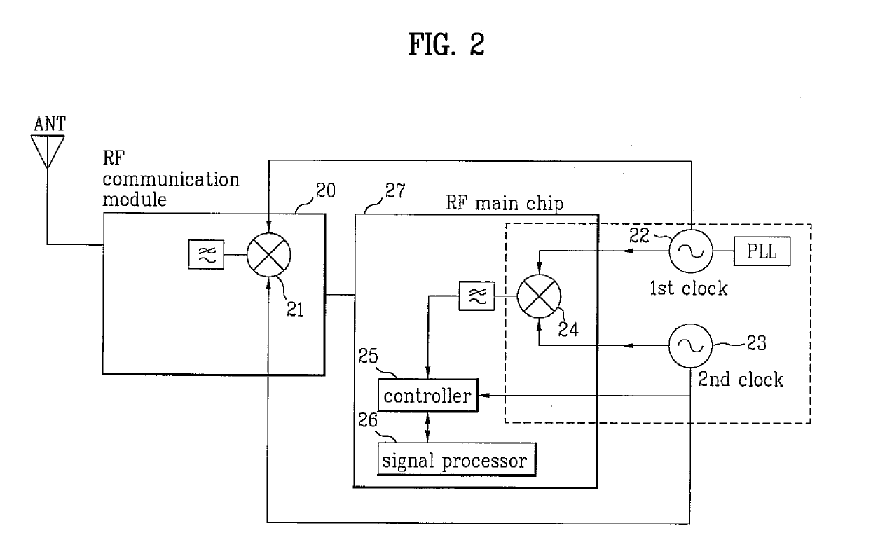

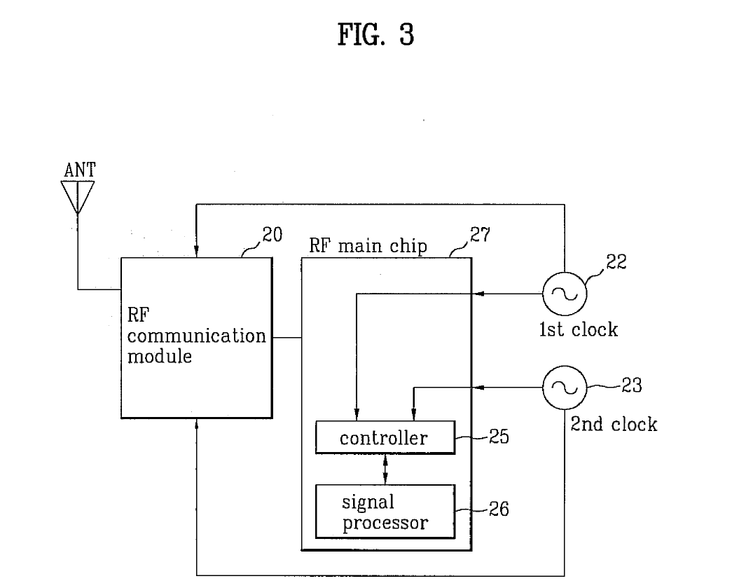

A mobile communication terminal which controls its clocks when receiving a wireless signal according to the present invention will now be described with reference to FIGS. 2 and 3.

As shown in FIG. 2, the mobile communication terminal includes a Radio Frequency (RF) communication module 20, a first mixer 21, a first oscillator 22, a second oscillator 23, a second mixer 24, a controller 25, a signal processor 26, and a RF main chip 27. Preferably, the first mixer 21 is included in the RF communication module 20 and the second mixer 24, the controller 25, and the signal processor 26 are included in the RF main chip 27.

Furthermore, the mobile communication terminal includes input, storage, and display means although they are not shown in the drawings.

The mobile communication terminal can be implemented in at least one of the EGSM, GSM, CDMA, TDMA, and Wideband CDMA (WCDMA) systems. However, for ease of explanation, the following description will be limited to the EGSM or GSM systems.

The first oscillator 22 produces a first clock which oscillates at a frequency which is free of interference from specific channels. The specific channels include 5th or 70th channel in the EGSM, for example.

The second oscillator 23 produces a second clock which oscillates at a frequency which is different from the frequency of the first clock.

The frequency of the first clock is higher than that of the second clock. That is, the first clock is a high clock having a high frequency, and the second clock is a slow clock having a low frequency. For example, the frequency of the first clock is 12.967232 MHz, and the frequency of the second clock is 32.768 KHz.

Preferably, a product of the frequency of the first clock multiplied by an integer is not equal to reception frequency of each of the specific channels.

The following is an exemplary comparison between the frequency of the first clock and the reception frequencies of the 5th and 70th channels (i.e., 936 MHz and 949 MHz, respectively) in the EGSM.

If the frequency of the first clock (i.e., 12.967232 MHz) is multiplied by integer 72, then the product is 933.640704 MHz. Moreover, if the frequency of the first clock (i.e., 12.967232 MHz) is multiplied by integer 73, then the product is 946.607936 MHz. As can be compared, the harmonic components) of the frequency of the first clock according to the present invention is not equal to the reception frequency of each of the 5th and 70th channels, which are 936 MHz and 949 MHz, respectively.

The term “mixer” generally refers to a circuit that mixes two or more input signals and produces a single output signal.

The first mixer 21 according to the present invention mixes the first and second clocks produced by the first and second oscillators 22 and 23, respectively. Thereafter, the first mixer 21 outputs a third clock as the mixing result. For example, the third clock may have a frequency that is equal to the sum of the frequencies of the first and second clocks. The output of the third clock from the first mixer 21 can be used as a main clock in the RF communication module 20.

The second mixer 24 according to the present invention mixes the first and second clocks produced by the first and second oscillators 22 and 23, respectively. Thereafter, the second mixer 24 outputs a third clock as the mixing result. For example, the third clock may have a frequency that is equal to the sum of the frequencies of the first and second clocks. The output of the third clock from the second mixer 24 can be used as a main clock in the controller 25.

The third clock used by the RF communication module 20 and the controller 25 can be produced by mixing the first and second clocks. The frequency of the third clock can be represented by 13 MHz, which is the sum of the frequencies of the first and second clocks. Here, the harmonic components of the third clock, which are the products of the frequency of the third clock multiplied by integers, are equal to the reception frequencies of the specific channels. For example, 72nd and 73rd harmonics of the third clock are equal to the reception frequency, i.e., 936 MHz, of the 5th channel and the reception frequency, i.e., 949 MHz, of the 70th channel in the EGSM.

As discussed, the RF main chip further includes the signal processor 26 which is used to process various signals inputted from the controller 25.

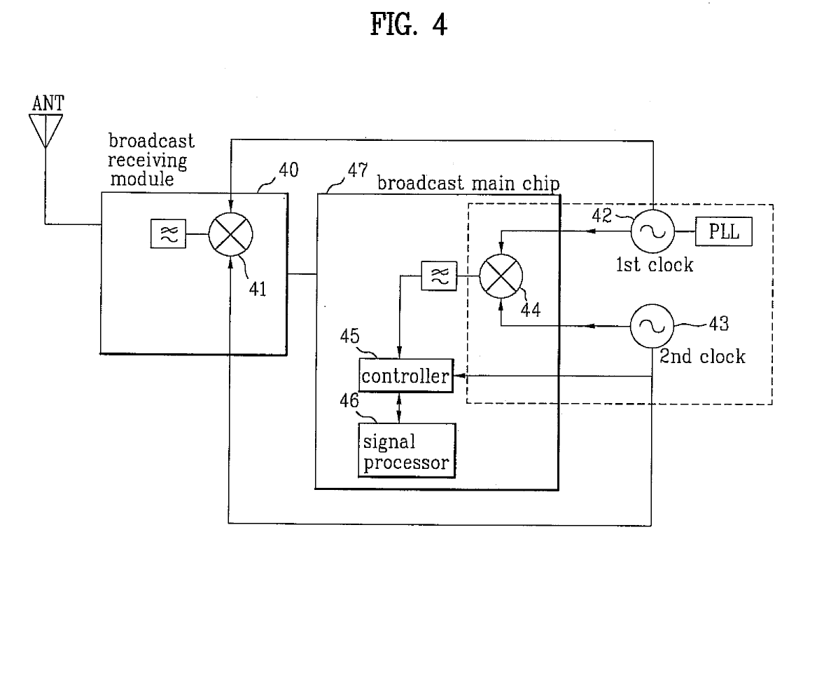

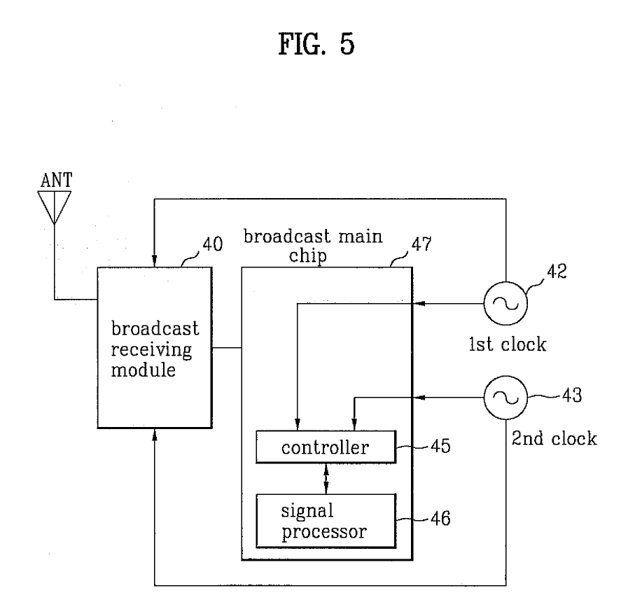

A mobile communication terminal which controls its clocks when receiving a broadcast signal according to the present invention will now be described with reference to FIGS. 4 and 5.

As shown in FIG. 4, the mobile communication terminal includes a broadcast receiving module 40, a first mixer 41, a first oscillator 42, a second oscillator 43, a second mixer 44, a controller 45, a signal processor 46, and a broadcast main chip 47. Preferably, the first mixer 41 is included in the broadcast receiving module 40 and the second mixer 44, the controller 45, and the signal processor 46 are included in the broadcast main chip 47.

The mobile communication terminal can be implemented in a broadcast system. Specifically, the mobile communication terminal can be implemented in at least one of the Terrestrial Digital Multimedia Broadcast (TDMB), Satellite DMB (SDMB), Digital Video Broadcasting—Handheld (DVB-H), Media FLO systems. For ease of explanation, the following description will be limited to the TDMB system.

The first oscillator 42 produces a first clock which oscillates at a frequency which is free of interference from specific broadcast channels. The specific broadcast channels include a 5D channel, an 8A channel, a 10C channel, or a 12D channel in the TDMB channels, for example.

The second oscillator 43 produces a second clock which oscillates at a frequency which is different from the frequency of the first clock. The frequency of the first clock is higher than that of the second clock. That is, the first clock is a high clock having a high frequency, and the second clock is a slow clock having a low frequency. For example, the frequency of the first clock is 16 MHz and the frequency of the second clock is 384 KHz.

Preferably, a product of the frequency of the first clock multiplied by an integer does not include the reception frequency band of each of the specific broadcast channels.

The following is an exemplary comparison between the frequency of the first clock and the reception frequency band of the 5D channel, Here, the 5D channel includes a low edge frequency of 179.296 MHz, a center frequency of 180.064 MHz, and a high edge frequency of 180.832 MHz.

The 11th multiple of 16 MHz (e.g., 16 MHz×11), which is the frequency of the first clock, is 176 MHz, and the 12th multiple (e.g., 16 MHz×12) is 192 MHz. Accordingly, any harmonic component of the frequency of the first clock according to the present invention is not included in the reception frequency band (179.292 MHz-180.832 MHz) of the 5D channel.

The first mixer 41 according to the present invention mixes the first and second clocks produced by the first and second oscillators 42 and 43, respectively. Thereafter, the first mixer 41 outputs a third clock as the mixing result. For example, the third clock may have a frequency that is equal to the sum of the frequencies of the first and second clocks. The output of the third clock from the first mixer 41 can be used as a main clock in the broadcast receiver module 40.

The second mixer 44 according to the present invention mixes the first and second clocks produced by the first and second oscillators 42 and 43, respectively. Thereafter, the second mixer 44 outputs a third clock as the mixing result. For example, the third clock may have a frequency that is equal to the sum of the frequencies of the first and second clocks. The output of the third clock from the second mixer 44 can be used as a main clock in the controller 45.

The third clock used by the broadcast receiving module 40 and the controller 45 can be produced by mixing the first and second clocks. The frequency of the third clock can be represented by 16.384 MHz, which is the sum of the frequencies of the first and second clocks. Here, the harmonic components of the third clock, which are the products of the frequency of the third clock multiplied by integers, are included in the reception frequency band of the specific broadcast channels.

As discussed, the broadcast main chip further includes the signal processor 46 which is used to process various signals input from the controller 45. More specifically, the signal processor 46 processes audio or video signal included in the broadcast signal.

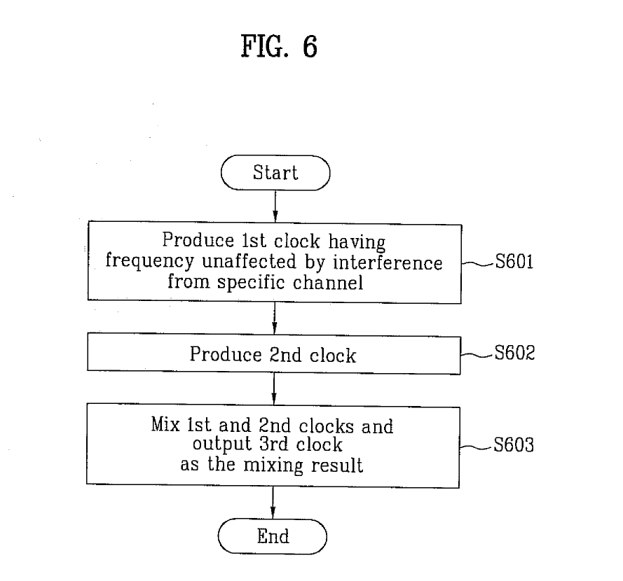

A clock control method for a mobile communication terminal according to the present invention is briefly described below with reference to FIG. 6.

As shown in FIG. 6, the clock control method includes producing a first clock which oscillates at a frequency which is free of interference from specific channels (S601). The method further includes producing a second clock oscillating at a frequency different from that of the first clock (S602) and mixing the first and second clocks to output a third clock as the mixing result(S603). For example, the third clock may have a frequency that is equal to the sum of the frequencies of the first and second clocks. As described above, the frequency of the first clock is higher than that of the second clock.

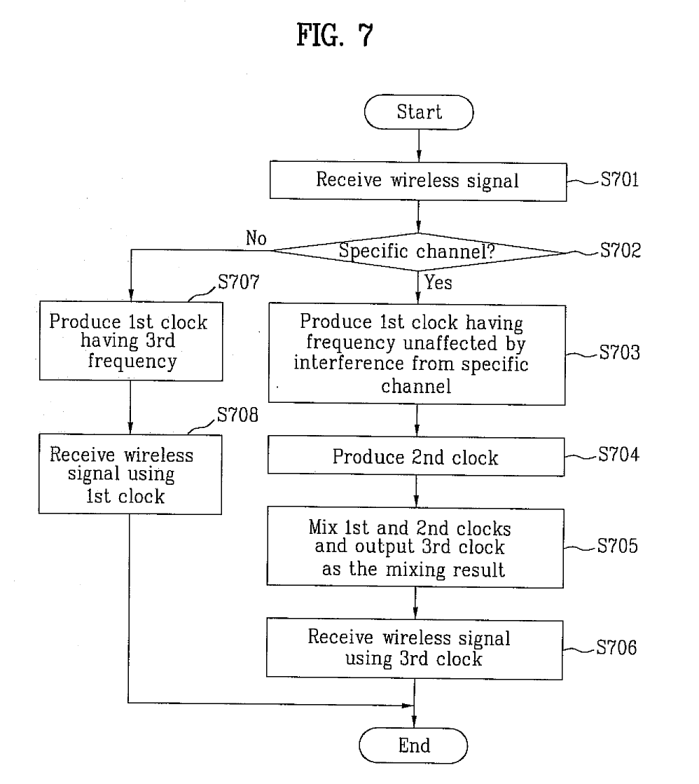

A method in which a mobile communication terminal controls its clocks when receiving a wireless signal will now be described with reference to FIGS. 2 and 7.

The RF communication module 20 receives a wireless signal through an antenna (S701). The mobile communication terminal then determines whether or not the channel of the received wireless signal is a specific channel that interferes with the main clock frequency of the RF communication module 20 (S702). For example, the specific channel is a 5th or 70th channel in the EGSM.

If it is determined that the channel of the received wireless signal is the specific channel, the first oscillator 22 produces a first clock having a frequency that is not affected by interference from the specific channel (S703). For example, the first oscillator 22 produces a first clock having a frequency of 12.967232 MHz. Here, the first clock signifies a high clock.

Preferably, a product of the frequency of the first clock multiplied by an integer is not equal to the reception frequency of the specific channel.

The following is an exemplary comparison between the frequency of the first clock and the reception frequency of the 5th or 70th channel.

The reception frequency of the 5th channel is 936 MHz, and the reception frequency of the 70th channel is 949 MHz. If the frequency of the first clock (i.e., 12.967232 MHz) is multiplied by integer 72, then the product is 933.640704 MHz. Moreover, if the frequency of the first clock (i.e., 12.967232 MHz) is multiplied by integer 73, then the product is 946.607936 MHz. As can be compared, the harmonic component(s) of the frequency of the first clock according to the present invention is not equal to the reception frequency of each of the 5th and 70th channels, which are 936 MHz and 949 MHz, respectively.

In addition, the second oscillator 23 produces a second clock having a frequency different from that of the first clock (S704). For example, the second clock 23 produces the second clock having a frequency of 32.768 MHz. Here, the second clock is a slow clock. That is, the frequency of the second clock is lower than that of the first clock.

The first and second mixers 21 and 24 mix the first and second clocks produced by the first and second oscillators 22 and 23, respectively. Thereafter, the first and second mixers 21 and 24 output a third clock as the mixing result (S705). For example, the third clock may have a frequency that is equal to the sum of the frequencies of the first and second clocks.

The third clock output from the first mixer 21 is used as a main clock in the RF communication module 20, and the third clock output from the second mixer 24 is used as a main clock in the controller 25.

For example, in the RF communication module 20, the first mixer 21 mixes the first clock having a frequency of 12.967232 MHz and the second clock having a frequency of 32.768 KHz. Thereafter, the first mixer outputs a third clock having a frequency of 13 MHz that is the sum of the frequencies of the first and second clocks.

Here, the frequency of the third clock, i.e., 13 MHz, multiplied by integer(s) is equal to the reception frequency of the specific channel.

Since the frequency of the main clock (i.e., 13 MHz) is used inside the RF communication module 20 or inside the GSM main chip 27 as described above, it is possible to prevent a reduction in the reception sensitivity due to channel interference caused when using a specific channel, for example, the 5th or 70th channel in the EGSM.

The RF communication module 20 receives a wireless signal using the third clock output from the first mixer 21 (S706).

The first oscillator 22 applies an oscillator, which can stably oscillate at two different frequencies (e.g., 13 MHz and 12.967232 MHz), and depending on the circumstances, can selectively oscillate at the two frequencies.

If it is determined that the channel of the received wireless signal is not the specific channel, the first oscillator 22 produces a main clock having the third frequency (i.e., the original main clock frequency) (S707).

For example, the first oscillator 22 can oscillate at a frequency selected from the two frequencies according to frequency characteristics of the channel. Specifically, when the channel of the received wireless signal is a channel other than the 5th and 70th channels in the EGSM frequency band, it is not necessary for the mobile communication terminal to mix the frequencies of the first and second clocks since the channel other than the 5th and 70th channels does not interfere with the main clock. Furthermore, the first oscillator 22 produces a clock having a frequency of 13 MHz, as shown in FIG. 3. This 13 MHz clock is a high or main clock.

The RF communication module 20 then receives a wireless signal using the first clock (i.e., the original main clock) (S708).

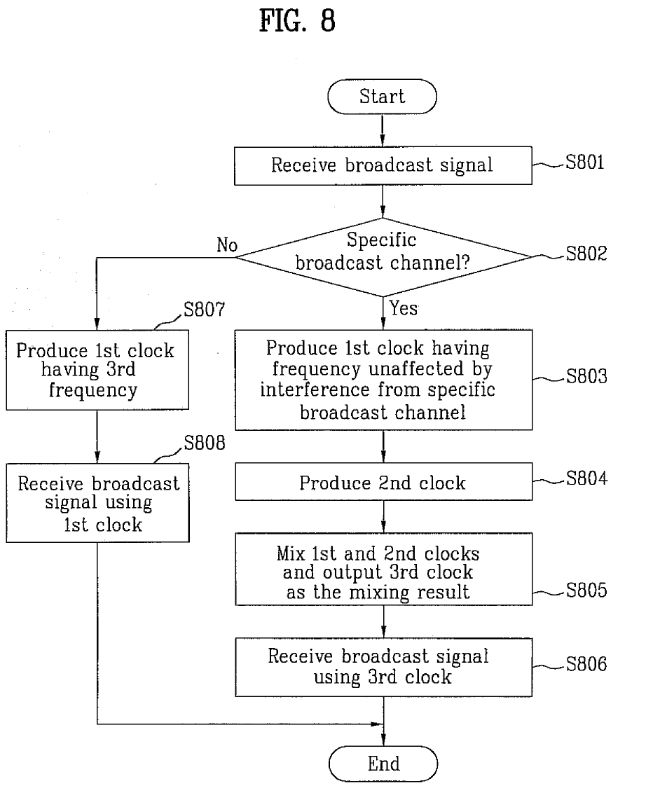

A method in which a mobile communication terminal controls its clocks when receiving a broadcast signal will now be described with reference to FIGS. 4 and 8.

The broadcast receiving module 40 receives a broadcast signal through an antenna (S801). The mobile communication terminal then determines whether or not the broadcast channel of the received broadcast signal is a specific broadcast channel that interferes with the main clock frequency of the broadcast receiving module 40 (S802). For example, the specific broadcast channel includes a 5D channel, an 8A channel, a 10C channel, or a 12D channel used in the TDME system.

If it is determined that the broadcast channel of the received broadcast signal is the specific broadcast channel, the first oscillator 42 produces a first clock having a frequency that is not affected by interference from the specific broadcast channel (S803). For example, the first oscillator 42 produces a first clock having a frequency of 16 MHz which is not affected by the specific broadcast channel. Here, the first clock is a high clock.

Preferably, a product of the frequency of the first clock multiplied by an integer is not included in the reception frequency band of the specific broadcast channel.

The second oscillator 43 produces a second clock having a frequency different from that of the first clock (S304). For example, the second oscillator 43 produces the second clock having a frequency of 384 MHz. Here, the second clock is a slow clock. That is, the frequency of the second clock is lower than that of the first clock.

Each of the first and second mixers 41 and 44 mixes the first and second clocks produced by the first and second oscillators 42 and 43 and outputs a third clock as the mixing result (S805). For example, the third clock may have a frequency that is equal to the sum of the frequencies of the first and second clocks.

The third clock output from the first mixer 41 is used as a main clock in the broadcast receiving module 40 and the third clock output from the second mixer 44 is used as a main clock in the controller 45. For example, in the broadcast receiving module 40, the first mixer 41 mixes the first clock having a frequency of 16 MHz and the second clock having a frequency of 384 KHz and then outputs a third clock having a frequency of 16.384 MHz which is the sum of the frequencies of the first and second clocks.

Here, the product of the frequency (i.e., 16.384 MHz) of the third clock multiplied by an integer is included in the reception frequency hand of the specific broadcast channel.

The broadcast receiving module 40 receives a broadcast signal using the third clock output from the first mixer 41 (S806).

An oscillator, which can stably oscillate at two different frequencies of 16 MHz and 16.384 MHz, is used as the first oscillator 42 so that the first oscillator 42 can selectively oscillate at the two frequencies.

If it is determined that the broadcast channel of the received broadcast signal is not the specific broadcast channel, the first oscillator 42 produces a main clock having the third frequency (i.e., the original main clock frequency) (S807).

The broadcast receiving module 40 then receives a broadcast signal using the first clock (i.e., the original main clock) (S808).

The present invention can be applied not only to any terminal that can be implemented in the conventional GSM system but also to any terminal that can be implemented in the EGSM, GSM, CDMA, TDMA, or WCDMA system.

In addition, the present invention can be applied not only to any terminal that can be implemented in the TDMB or SDMB system but also to any terminal that can be implemented in a broadcast system such as the DVB-H or Media FLOW system.

The prevent invention can also be applied to any communication product wherein, when its main clock interferes with a specific channel to cause a reduction in the reception sensitivity of the specific channel, a main clock having a frequency equal to the sum of frequencies of two or more clocks, which is produced by mixing the clocks, is allowed to be used inside each of its chips.

As is apparent from the above description, the present invention provides a mobile communication terminal having a clock control function and a clock control method for the same, which have a variety of advantages.

For example, according to the present invention, a main clock having a frequency equal to the sum of the frequencies of a plurality of clocks, which is produced by mixing the plurality of clocks inside an RF communication module, is used as an operating clock of the RF communication module, thereby avoiding channel interference when receiving wireless signals. This prevents a reduction in the reception sensitivity of audio signals that occurs when performing voice communication through a specific channel due to interference with the specific channel.

In addition, according to the present invention, a main clock having a frequency equal to the sum of the frequencies of a plurality of clocks, which is produced by mixing the plurality of clocks inside a broadcast receiver module, is used as an operating clock of the broadcast receiver module, thereby avoiding channel interference when receiving broadcast signals. This prevents a reduction in the broadcast reception sensitivity that occurs when receiving broadcast signals through a specific broadcast channel due to interference with the specific broadcast channel.

Further, according to the present invention, the main clock can selectively oscillate at different frequencies according to frequency characteristics of the channel.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A mobile communication terminal having a clock control function, the terminal comprising:
a first oscillator configured to produce a first clock having a frequency which is unaffected by interference from a specific channel;
a second oscillator configured to produce a second clock having a frequency different from the frequency of the first clock; and
a mixer configured to mix the first clock and the second clock and output a third clock as the mixing result.

2. The mobile communication terminal of claim 1, wherein the third clock has a frequency equal to the sum of the frequency of the first clock and the frequency of the second clock.

3. The mobile communication terminal of claim 1, further comprising:
a radio frequency (RF) communication module configured to communicate a wireless signal with a base station; and
a controller configured to control an operation associated with the communication of the wireless signal,
wherein the mixer includes a first mixer and a second mixer, each of the first mixer and a second mixer mixes the first and second clocks and outputs a third clock as the mixing result.

4. The mobile communication terminal of claim 3, wherein the first mixer is included in the RF communication module.

5. The mobile communication terminal of claim 3, wherein the RF communication module uses, as a main clock, the third clock output from the first mixer, and the controller uses, as a main clock, the third clock output from the second mixer.

6. The mobile communication terminal of claim 1, further comprising:
a broadcast receiving module configured to receive a broadcast signal through a broadcast channel; and
a controller configured to control an operation associated with the reception of the broadcast signal,
wherein the mixer includes a first mixer and a second mixer, each of the first mixer and a second mixer mixes the first and second clocks and outputs a third clock as the mixing result.

7. The mobile communication terminal of claim 6, wherein the first mixer is included in the broadcast receiving module.

8. The mobile communication terminal of claim 6, wherein the broadcast receiving module uses, as a main clock, the third clock output from the first mixer, and the controller uses, as a main clock, the third clock output from the second mixer.

9. The mobile communication terminal of claim 1, wherein the frequency of the first clock is higher than the frequency of the second clock.

10. The mobile communication terminal of claim 1, wherein, in a global system for mobile communications (GSM), the frequency of the first clock is 12.967232 MHz, the frequency of the second clock is 32.768 KHz, and the frequency of the third clock is 13.000 MHz.

11. The mobile communication terminal of claim 1, wherein, in a terrestrial digital multimedia broadcasting (TDMB) system, the frequency of the first clock is 16 MHz, the frequency of the second clock is 384 KHz, and the frequency of the third clock is 16.384 MHz.

12. The mobile communication terminal of claim 1, wherein the frequency of the specific channel is not equal to the frequency of the first clock or the frequency of the second clock, which is multiplied by an integer, and is equal to a frequency of the third clock multiplied by an integer.

13. A clock control method for a mobile communication terminal, the method comprising:
producing a first clock having a frequency which is unaffected by interference from a specific channel;
producing a second clock having a frequency different from the frequency of the first clock; and
mixing the first clock and the second clock and outputting a third clock as the mixing result.

14. The clock control method of claim 13, wherein the third clock has a frequency equal to the sum of the frequency of the first clock and the frequency of the second clock.

15. The clock control method of claim 13, wherein the clock control method is implemented in at least one of a wireless communication system and a broadcast system.

16. The clock control method of claim 13, further comprising receiving a wireless signal using the third clock as a main clock.

17. The clock control method of claim 16, wherein mixing the first and second clocks and outputting the third clock includes mixing the first clock and the second clock in a module that receives the wireless signal and outputting the third clock.

18. The clock control method of claim 13, further comprising receiving a broadcast signal through a broadcast channel using the third clock as a main clock.

19. The clock control method of claim 18, wherein mixing the first and second clocks and outputting the third clock includes mixing the first clock and the second clock in a module that receives the broadcast signal and outputting the third clock.

20. The clock control method of claim 13, wherein a frequency of the specific channel is not equal to the frequency of the first clock or the frequency of the second clock, which is multiplied by an integer, and is equal to a frequency of the third clock multiplied by an integer.
